(19) United States
(12) Patent Application Publication
(10) Pub. No.: US 2026/0223568 A1
(43) Pub. Date: Jul. 30, 2026

(54) LIGHT EMITTING DISPLAY DEVICE

(71) Applicant: LG Display Co., Ltd., Seoul (KR)

(72) Inventors: Hee-Su BYEON, Paju-si (KR); Se-In SON, Paju-si (KR); Pu-Reum KIM, Paju-si (KR)

(73) Assignee: LG Display Co., Ltd., Seoul (KR)

(21) Appl. No.: 19/380,489

(22) Filed: Nov. 5, 2025

(30) Foreign Application Priority Data
Dec. 24, 2024 (KR) 10-2024-0195953

(51) Int. Cl. H10K 59/80; H10K 59/124; H10K 59/35

(52) U.S. Cl. CPC H10K 59/80517; H10K 59/124; H10K 59/353

(57) ABSTRACT

A light emitting display device includes a substrate having subpixels each having an emission region and a contact region, a first reflective plate disposed in the emission region, a main electrode of a first electrode, a light emitting layer, and a second electrode which are laminated on the first reflective plate and are disposed in the emission region and the contact region, and a laminated structure in the contact region and interposed between the main electrode and the light emitting layer. The laminated structure includes a planarization pattern and a second reflective plate on the planarization pattern. A micro cavity structure configured with the first reflective plate and the second electrode in the emission region generates light of the same color as a micro cavity structure configured with the second reflective plate and the second electrode in the contact region.

### CROSS REFERENCE TO RELATED APPLICATIONS

The present application claims priority to Korean Patent Application No. 10-2024-0195953 filed in the Republic of Korea on December 24, 2024, which is hereby expressly incorporated by reference in its entirety for all purposes as if fully set forth herein.

### BACKGROUND

### Field of the Invention

The present invention relates to a light emitting display device.

### Discussion of the Related Art

Recently, flat panel display devices with excellent characteristics such as thinness, weight reduction, and low power consumption have been widely developed and applied to various fields.

Among the flat panel display devices, light emitting display devices equipped with light emitting elements such as light emitting diodes are display devices that emit light when charges are injected into a light emitting layer formed between an anode and a cathode, and electrons and holes are paired and then extinguished.

Further, subpixels in the light emitting display device can be configured with a micro cavity structure to improve emission efficiency of colors of the subpixels.

However, the subpixel has a contact region where a transistor and an anode of a light emitting diode are connected, a lateral leakage current from an emission region can cause emission in the contact region. In the contact region, a reflective plate has an uneven shape due to a contact hole, and thus the contact region differs from a resonant distance of the micro cavity structure of the emission region.

Consequently, in the subpixel, light generated in the contact region has a different color from the light generated in the emission region. This can cause a color mixing phenomenon in the subpixel due to the light in the contact region, which can result in a decrease in color gamut.

### SUMMARY OF THE INVENTION

An advantage of the present invention is to provide a light emitting display devicethat can reduce or prevent a color mixing phenomenon in a subpixel and decrease in color gamut due to light of a different color from that of an emission region being generated in a contact region.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a light emitting display device includes a substrate including a plurality of subpixels each including an emission region and a contact region; a first reflective plate disposed in the emission region on the substrate; a first electrode including a main electrode and laminated on the first reflective plate; a light emitting layerlaminated on the main electrode; a second electrode laminated on thelight emitting layer and being semi-transparent, wherein the main electrode, the light emitting layer and the second electrode are disposed on the emission region and the contact region;and a laminated structure which is in the contact region, is interposed between the main electrode and the light emitting layer, and includes a planarization pattern on the main electrode and a second reflective plate on the planarization pattern, wherein a micro cavity structure configured with the first reflective plate and the second electrode in the emission region generates light of a same color as a micro cavity structure configured with the second reflective plate and the second electrode in the contact region.

It is to be understood that both the foregoing general description and the following detailed description are examples and explanatory and are intended to provide further explanation of the invention as claimed.

### BRIEF DESCRIPTION OF THE DRAWINGS

The accompanying drawings, which are included to provide a further understanding of the present invention and are incorporated in and constitute a part of this specification, illustrate embodiments of the present invention and together with the description serve to explain the principles of the present invention. In the drawings.

FIG. 1 is a plan view schematically illustrating the arrangement of subpixels in a light emitting display device according to a first embodiment of the present invention;

FIGS. 2 and 3 are cross-sectional views taken along lines II-II’ and III-III’ of FIG. 1, respectively;

FIGS. 4, 5, and 6 are cross-sectional views taken along lines IV-IV’, V-V’, and VI-VI’ of FIG. 1, respectively;

FIG. 7 is a cross-sectional view illustrating a structure of an emission region of a subpixel of a light emitting display device according to a second embodiment of the present invention;

FIGS. 8, 9 and 10 are cross-sectional views illustrating the structures of emission region and contact region of red, green, and blue subpixels, respectively, according to the second embodiment of the present invention;

FIGS. 11, 12 and 13 are cross-sectional views illustrating the structures of emission region and contact region of red, green, and blue subpixels, respectively, according to a third embodiment of the present invention; and

FIGS. 14, 15 and 16 are cross-sectional views illustrating the structures of emission region and contact region of red, green, and blue subpixels, respectively, according to a fourth embodiment of the present invention.

### DETAILED DESCRIPTION OF THE EMBODIMENTS

Advantages and features of the present invention and methods of achieving them will be apparent with reference to the embodiments of the present invention described below in detail with the accompanying drawings. However, the present invention is not limited to the embodiments disclosed below, but can be realized in a variety of different forms, and only these embodiments allow the present invention to be complete. The present invention is provided to fully inform the scope of the invention to the skilled in the art of the present invention, and the present inventioncan be defined by the scope of the claims.

The shapes, sizes, proportions, angles, numbers, and the like disclosed in the drawings forexplaining the embodiments of the present invention are illustrative, and the present invention is not limited to the illustrated matters. The same reference numerals refer to the same components throughout the description.

Furthermore, in describing the present invention, if it is determined that a detailed description of the related known technology unnecessarily obscure the subject matter of the present invention, the detailed description thereof can be omitted or briefly provided. When 'comprising', 'including', 'having', 'consisting', and the like are used in this invention other parts can be added unless 'only' is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as 'on', 'over', 'above', 'below', 'beside', 'under', and the like, one or more other parts can be positioned between such two parts unless 'right' or 'directly' is used.

In the case of a description of a temporal relationship, for example, when a temporal precedence is described as 'after', 'following', 'before', and the like, cases that are not continuous can be included unless 'directly' or 'immediately' is used.

In describing components of the present invention, terms such as first, second and the like can be used. These terms are only for distinguishing the components from other components, and an essence, order, sequence, or number of the components is not limited by the terms.

Respective features of various embodiments of the present inventioncan be partially or wholly connected to or combined with each other and can be technically interlocked and driven variously, andrespective embodiments can be independently implemented from each other or can be implemented together with a related relationship. Further, the term “can” fully encompasses all the meanings and coverages of the term “may” and vice versa.

Hereinafter, embodiments of the present invention are described in detail with reference to the drawings. Meanwhile, in the following embodiments, the same and like reference numerals are assigned to the same and like components, and detailed descriptions thereof can be omitted or briefly provided. Further, all the components of each display device/apparatus according to all embodiments of the present invention are operatively coupled and configured.

### First Embodiment

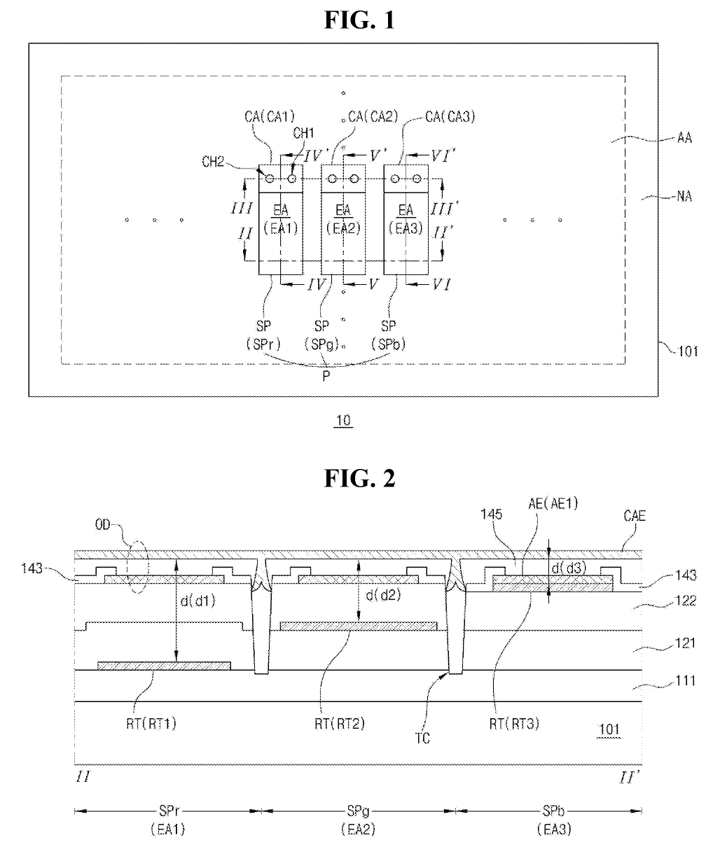

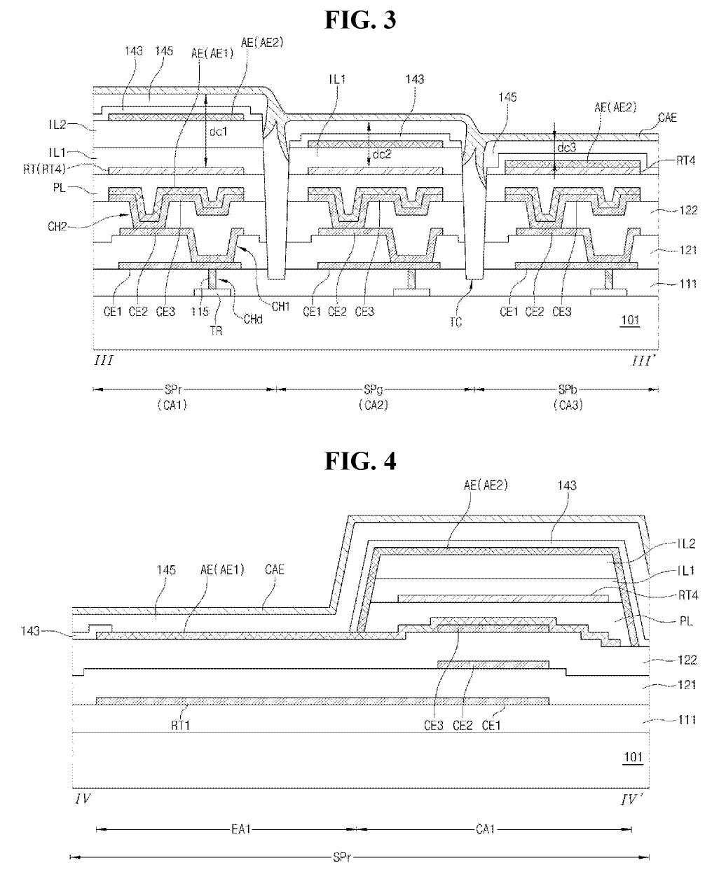

FIG. 1 is a plan view schematically illustrating arrangement of subpixels in a light emitting display device according to a first embodiment of the present invention. FIGS. 2 and 3 are cross-sectional views taken along lines II-II’ and III-III’ of FIG. 1, respectively. Particularly, FIG. 2 illustrates a structure of an emission region of a subpixel, and FIG. 3 illustrates a structure of a contact region of a subpixel.

Prior to a detailed description, a light emitting display device 10 according to the first embodiment of the present invention can include any type of display device that displays images using a light emitting diode OD which is a self-luminous element.

In this embodiment, for convenience of explanation, an organic light emitting display device can be used as the light emitting display device 10.

In addition, the light emitting display device 10 can be a top emission type display device.

Referring to FIGS. 1 to 3, the light emitting display device 10 (or its display panel) of this embodiment can include a display region AA (or active area) for displaying an image, and a non-display region NA (or non-active area) located outside the display region AA and surrounding the display region AA. The non-display region NA can surround the display region AA entirely or only in part(s).

The display region AA can include a plurality of subpixels SP arranged along a plurality of row lines (or horizontal lines) and a plurality of column lines (or vertical lines) on a substrate 101.

Meanwhile, a plurality of gate lines (or scan lines) extending along the row direction (or horizontal direction or first direction) and a plurality of data lines extending along the column direction (or vertical direction or second direction) can be formed on the substrate 101. Each subpixel SP can be connected to the corresponding gate line and data line.

Furthermore, a power line transmitting a high-potential driving voltage and a power line transmitting a low-potential driving voltage can be formed on the substrate 101. The high-potential driving voltage and the low-potential driving voltage can be applied to the subpixel SP.

The plurality of subpixels SP formed on the substrate 101 can include subpixels SP of different colors that constitute a pixel P which is a unit for displaying a color image. For example, the subpixels SP constituting the pixel P can include subpixels SP that display first, second, and third colors, respectively, for example, red, green, and blue subpixels (or first, second, and third subpixels) SPr, SPg, and SPb that display red, green, and blue, respectively. As another example, the subpixels SP constituting the pixel P can further include a white subpixel that displays white.

In this embodiment, the case where the pixel P is configured with the red, green, and blue subpixels SPr, SPg, and SPb is taken as an example.

The red, green, and blue subpixels SPr, SPg, and SPb can be arranged in various configurations. For example, as illustrated in FIG. 1, the subpixels SP can be arranged in a stripe type, with subpixels SP of the same color can be arranged in a stripe configuration in which subpixels SP of the same color arranged in the column direction and subpixels SP of different colors alternately arranged in the row direction, but not limited thereto.

Each subpixel SP can include the light emitting diode OD which is a light emitting element. Furthermore, the subpixel SP can include a pixel driving circuit that drives the light emitting diode OD. The pixel driving circuit can include a plurality of thin film transistors TR including a driving transistor, and at least one capacitor. In this case, during an emission period, the driving transistor can be turned on to generate an emission current, and the emission current can be provided to the light emitting diode OD to perform an emission operation.

Each subpixel SP can include, for example, an emission region EA, which is an effective emission region that actually generates light of a corresponding color, and a non-emission region surrounding the emission region EA.A color light of the emission region EA may be referred to as a color light of the subpixel SP herein.

The emission region EA can be a region where the light emitting diode OD is formed, and thus, light generated from the light emitting diode OD can be output in the emitting region EA.

A contact region CA can be defined in the non-emitting region, and the light emitting diode OD can be connected to the thin film transistor TR of the pixel driving circuit in the contact region CA. In the contact region CA, a drain electrode of the thin film transistor TR and the first electrode (or anode electrode) AE, which is a lower electrode of the light emitting diode OD, can be electrically connected, so that a driving signal (or driving current) from the thin film transistor TR can be applied to the first electrode AE. In this embodiment, for convenience of explanation, an example is given in which the contact region CA is disposed on one side of the emission region EA, for example, on an upper side of the emission region EA, as shown in FIG. 1.

In addition, for convenience of explanation, the emission region EA and the contact region CA of the red subpixel SPr can be referred to as a first emission region EA1 and a first contact region CA1, the emission region EA and the contact region CA of the green subpixel SPg can be referred to as a second emission region EA2 and a second contact region CA2, and the emission region EA and the contact region CA of the blue subpixel SPb can be referred to as a third emission region EA3 and a third contact region CA3.

To enhance emission efficiency of a color of each subpixel SP, each subpixel SP can be implemented with a micro cavity structure which is configured with a semi-transparent laminated film and a reflective laminated film that are arranged vertically with a light emitting layer 145 interposed therebetween.

For example, the red subpixel SPr, the green subpixel SPg, and the blue subpixel SPb can emit light of different colors, i.e., different wavelengths, and thus they can have different cavity thicknesses i.e., resonant distances (d: d1, d2, and d3), in their respective emission regions (EA: EA1, EA2, and EA3).

In this regard, the red, green, and blue subpixels SPr, SPg, and SPb can have the resonant distances d proportional to their color wavelengths (or half-wavelengths). The resonant distance d of each subpixel SP can be matched to an integer multiple of the half-wavelength of its corresponding color.

The red subpixel SPr, which outputs a color of the longest wavelength, can have a relatively largest first resonant distance d1 in the corresponding first emission region EA1. The green subpixel SPg, which outputs a color of the middle wavelength, can have a second resonant distance d2 smaller than the first resonant distance d1 in the corresponding second emission region EA2. The blue subpixel SPb, which outputs a color of the shortest wavelength, can have a third resonance distance d3 smaller than the second resonance distance d2 in the corresponding third emission region EA3.

As such, by utilizing the micro cavity structure, color purity and emission efficiency can be improved.

In this embodiment, for the contact region CA of each subpixel SP, a micro cavity structure having a resonant distance capable of emitting a color light of each subpixel SP can be formed.

In this regard, the light emitting layer 145 in the subpixel SP can extend over the contact region CA, thereby allowing a current of the emission region EA to flow laterally and leak into the contact region CA. This lateral leakage current can cause emission from the light emitting layer 145 located in the contact region CA.

In this embodiment, in the contact region CA of the subpixel SP, a micro cavity structure having a resonant distance, which is substantially equal to the resonant distance d of the emission region EA of the subpixel SP, can be formed.

Referring to FIGS. 2 and 3, for example, in the red subpixel SPr, a micro cavity structure having a fourth resonant distance dc1 can be implemented in the first contact region CA1, corresponding to the first resonant distance d1 of the first emission region EA1. In addition, in the green subpixel SPg, a micro cavity structure having a fifth resonant distance dc2 can be implemented in the second contact region CA2, corresponding to the second resonant distance d2 of the second emission region EA2. In addition, in the blue subpixel SPb, a micro cavity structure having a sixth resonant distance dc3 can be implemented in the third contact region CA3, corresponding to the third resonant distance d3 of the third emission region EA3.

Accordingly, in the subpixel SP, the contact region CA can generate and output color light of substantially the same wavelength range as the corresponding emission region EA.

Therefore, a color mixing phenomenon of the subpixel SP, which occurs when the contact region CA generates color light of a different wavelength from the emission region EA due to the lateral leakage current, can be prevented (or reduced), thereby improving the color gamut of the subpixel SP.

As such, in this embodiment, in the contact region CA of each subpixel SP, the micro cavity structure can be formed which can generate color light of substantially the same wavelength as color light of each subpixel SP.

The micro cavity structure of the contact region CA of this embodiment can be described in more detail below.

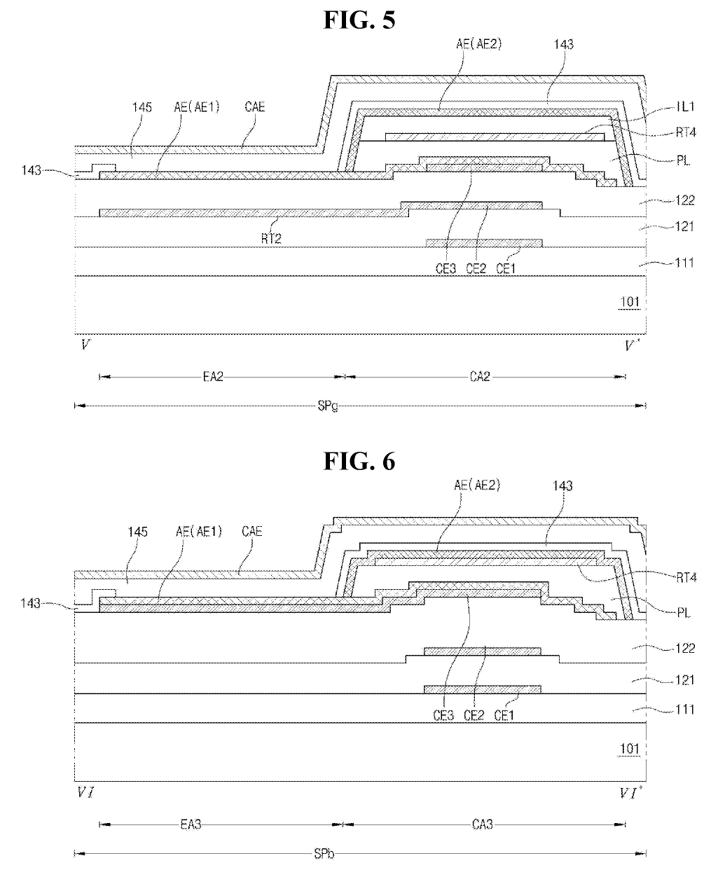

FIGS. 4, 5, and 6 are cross-sectional views taken along lines IV-IV’, V-V’, and VI-VI’ of FIG. 1, respectively. FIG. 4 illustrates structures of emission region and contact region of a red subpixel, FIG. 5 illustrates structures of emission region and contact region of a green subpixel, and FIG. 6 illustrates structures of emission region and contact region of a blue subpixel.

With reference to FIGS. 4 to 6 along with FIGS. 1 to 3, a cross-sectional structure of the light emitting display device 10 of this embodiment can be described.

The substrate 101 of the light emitting display device 10 can be an insulating substrate, such as a glass substrate or a plastic substrate. As another example, the substrate 101 can be a silicon substrate (or silicon wafer) formed of crystalline silicon (e.g., single-crystal silicon) that functions as a semiconductor, and thus may be referred to as a semiconductor substrate. In this case, there is an advantage of effectively implementing a small-sized display device requiring high resolution.

In this embodiment, for convenience of explanation, an insulating substrate is used as an example.

A plurality of thin film transistors TR can be formed in each subpixel SP on the substrate 101. Meanwhile, in this embodiment, for convenience of explanation, in FIG. 3, one thin film transistor TR connected to the light emitting diode OD is illustrated in each subpixel SP. The thin film transistor TR can be an emission control transistor or a driving transistor, but not limited thereto.

The thin film transistor TR can include a semiconductor layer, a gate insulating layer, a gate electrode, a source electrode, and a drain electrode. Here, the thin film transistor TR can be a thin film transistor of a bottom-gate structure in which the gate electrode is positioned below the semiconductor layer, or be a thin film transistor of a top-gate structure in which the gate electrode is positioned over the semiconductor layer

In a case where a semiconductor substrate is used as the substrate 101, an active region functioning as a semiconductor layer can be formed within the semiconductor substrate.

A passivation layer 111 can be formed on the thin film transistor TR. The passivation layer 111 can be formed in a single-layered structure or a multi-layered structure. The passivation layer 111 can be formed of an organic insulating material and/or an inorganic insulating material.

The passivation layer 111 can be formed substantially over the entire surface of the substrate 101 while covering the thin film transistor TR. The passivation layer 111 can have a flat upper surface, but not limited thereto. For example, at least an upper portion of the passivation layer 111 can be formed of a planarization layer.

A drain contact hole CHd, which is a contact hole exposing one electrode of the thin film transistor TR, for example, a drain electrode of the thin film transistor TR, can be formed in the passivation layer 111.

A conductive pattern 115 can be formed within the drain contact hole CHd of the passivation layer 111, and the conductive pattern 115 can contact the drain electrode of the thin film transistor TR.

On the substrate 101 on which the passivation layer 111 is formed, for example, a reflective plate RT implementing a micro cavity structure can be formed corresponding to the red subpixel SPr, more specifically, the first emission region EA1. The reflective plate RT formed in the red subpixel SPr can be referred to as a first reflective plate RT1.

Here, the first reflective plate RT1 can be formed of a highly reflective metal, such as, but not limited to, Ag, Al, Mo, Ti, or an APC (Al-Pd-Cu) alloy.

Referring to FIG. 3, on the passivation layer 111, a first connection electrode (or first intermediate electrode) CE1 can be formed in the contact region CA of each subpixel SP. For example, the first connection electrode CE1 can be formed of the same material as and in the same process as the first reflective plate RT1, and thus the first connection electrode CE1 can be positioned at the same layer as the first reflective plate RT1.

The first connection electrode CE1 formed in the contact region CA can be connected to the thin film transistor TR by making contact with the conductive pattern 115 filling the drain contact hole CHd.

In the red subpixel SPr, the first reflective plate RT1 and the first connection electrode CE1 can be formed integrally. In this regard, the first reflective plate RT1 can be formed to extend from the first connection electrode CE1 to the first emission region EA1. As another example, the first reflective plate RT1 and the first connection electrode CE1 can be formed separately and in a disconnected form.

A first insulating layer (or dielectric layer) 121 can be formed on the substrate 101 where the first reflective plate RT1 and the first connection electrode CE1 are formed. The first insulating layer 121 can be formed in a single-layered or multi-layered structure. The first insulating layer 121 can be formed of an organic insulating material and/or an inorganic insulating material.

The first insulating layer 121 can be formed substantially over the entire surface of the substrate 101, covering the first reflective plate RT1 and the first connection electrode CE1.

Here, a first contact hole CH1 can be formed in the first insulating layer 121 to expose the first connection electrode CE1 in the contact region CA of each subpixel SP.

On the substrate 101 on which the first insulating layer 121 is formed, for example, a reflective plate RT implementing a micro cavity structure can be formed corresponding to the green subpixel SPg, and more specifically, the second emission region EA2. The reflective plate RT formed in the green subpixel SPg can be referred to as a second reflective plate RT2.

Here, similar to the first reflective plate RT1, the second reflective plate RT2 can be formed of a highly reflective metal, such as Ag, Al, Mo, Ti, or an APC (Al-Pd-Cu) alloy, but not limited thereto.

Referring to FIG. 3, on the first insulating layer 121, a second connection electrode (or second intermediate electrode) CE2 can be formed in the contact region CA of each subpixel SP. For example, the second connection electrode CE2 can be formed of the same material as and in the same process as the second reflective plate RT2, and thus the second connection electrode CE2 can be positioned at the same layer as the second reflective plate RT2.

The second connection electrode CE2 formed in the contact region CA can contact the first connection electrode CE1 through the first contact hole CH1. Accordingly, the second connection electrode CE2 can be connected to the thin film transistor TR.

In the green subpixel SPg, the second reflective plate RT2 and the second connection electrode CE2 can be formed integrally. In this case, the second reflective plate RT2 can be formed to extend from the second connection electrode CE2 to the second emission region EA2. As another example, the second reflective plate RT2 and the second connection electrode CE2 can be formed separately and in a disconnected form.

A second insulating layer (or dielectric layer) 122 can be formed on the substrate 101 on which the second reflective plate RT2 and the second connection electrode CE2 are formed. The second insulating layer 122 can be formed as a single-layered or multi-layered structure. The second insulating layer 122 can be formed of an organic insulating material and/or an inorganic insulating material.

This second insulating layer 122 can be formed substantially over the entire surface of the substrate 101, covering the second reflective plate RT2 and the second connection electrode CE2.

Here, a second contact hole CH2 can be formed in the second insulating layer 122 to expose the second connection electrode CE2 in the contact region CA of each subpixel SP.

The second contact hole CH2 can be formed at a position spaced apart from and not overlapping the first contact hole CH1, but not limited thereto.

Referring to FIG. 2, on the substrate 101 on which the second insulating layer 122 is formed, for example, a reflective plate RT implementing a micro cavity structure can be formed corresponding to the blue subpixel SPb, or more specifically, the third emission region EA3. The reflective plate RT formed in the blue subpixel SPb can be referred to as a third reflective plate RT3.

Here, similar to the first and second reflective plates RT1 and RT2, the third reflective plate RT3 can be formed of a highly reflective metal, such as Ag, Al, Mo, Ti, or an APC (Al-Pd-Cu) alloy, but not limited thereto.

Referring to FIG. 3, on the second insulating layer 122, a third connection electrode (or third intermediate electrode) CE3 can be formed in the contact region CA of each subpixel SP. For example, the third connection electrode CE3 can be formed of the same material as and in the same process as the third reflective plate RT3, and thus the third connection electrode CE3 can be positioned at the same layer as the third reflective plate RT3.

The third connection electrode CE3 formed in the contact region CA can contact the second connection pattern CE2 through the second contact hole CH2. Accordingly, the third connection electrode CE3 can be connected to the thin film transistor TR.

In the blue subpixel SPb, the third reflective plate RT3 and the third connection electrode CE3 can be formed integrally. In this case, the third reflective plate RT3 can be formed to extend from the third connection electrode CE3 to the third emission region EA3. As another example, the third reflective plate RT3 and the third connection electrode CE3 can be formed separately and in a disconnected form.

A first electrode (AE: AE1) constituting a light emitting diode OD of each subpixel SP can be formed on the substrate 101 having the third reflective plate RT3 and the third connection electrode CE3.

For example, the first electrode AE can be formed for each subpixel SP, and the first electrodes AE of adjacent subpixels SP can be separated and disconnected from each other.

The first electrode AE can be formed continuously along the emission region EA and the contact region CA of each subpixel SP.

In this case, a portion of the first electrode AE located in the emission region EA can constitute a lower electrode of the light emitting diode OD.

Furthermore, a portion of the first electrode AE located in the contact region CA can be formed, for example, along an upper surface of the third connection electrode CE3 and in contact with an upper surface of the third connection electrode CE3.

Accordingly, in each subpixel SP, the first electrode AE can be electrically connected to the thin film transistor TR through the first to third connection electrodes CE1 to CE3 that are formed in the contact region CA.

Here, in the blue subpixel SPb, the first electrode AE can contact the third reflective plate RT3 therebelow in the third emission region EA3. Furthermore, in the red subpixel SPr, the first electrode AE can contact the second insulating layer 122 therebelow in the first emission region EA1. Furthermore, in the green subpixel SPg, the first electrode AE can contact the second insulating layer 122 therebelow in the second emission region EA2.

The first electrode AE can be formed of, for example, a transparent electrode having transmissive characteristics. The first electrode AE can be formed of, for example, a transparent conductive material such as ITO, IZO, or ITZO, but not limited thereto.

The first electrode AE, below the light emitting layer 145, constituting the light emitting diode OD can be referred to as a main electrode AE1.

On the substrate 101 on which the main electrode AE1 is formed, the emission region EA and the contact region CA of each subpixel SP can have different laminated structures.

Regarding the laminated structure of the emission region EA, a light emitting layer 145 can be formed on the main electrode AE1, and a second electrode (or cathode electrode) CAE can be formed on the light emitting layer 145.

As such, the main electrode AE1, the light emitting layer 145, and the second electrode CAE, which are sequentially laminated in the emission region EA, can constitute the light emitting diode OD.

Here, the light emitting layer 145 can be configured as a white light emitting layer that emits white light. Accordingly, the light emitting diodes OD of all subpixels SP can generate identical white light.

The second electrode CAE can be configured as a semi-transparent electrode. The second electrode CAE can be formed of a metal such as, but not limited to, Mg, Ag, or an alloy of Mg and Ag (Mg:Ag).

The semi-transparent second electrode CAE, together with the reflective plate RT positioned below it, can implement a micro cavity structure for the emission region EA of each subpixel SP.

For example, in the first emission region EA1 of the red subpixel SPr, a micro cavity structure configured with the first reflective plate RT1 and the second electrode CAE which are spaced apart by a first resonant distance d1 can be implemented. Accordingly, in the first emission region EA1 of the red subpixel SPr, white light generated from the light emitting diode OD can be reflected between the first reflective plate RT1 and the second electrode CAE, thereby generating red light according to a micro cavity effect and outputting it upwards.

In the second emission region EA2 of the green subpixel SPg, a micro cavity structure configured with the second reflective plate RT2 and the second electrode CAE which are spaced apart by a second resonant distance d2 can be implemented. Accordingly, in the second emission region EA2 of the green subpixel SPg, white light generated from the light emitting diode OD can be reflected between the second reflective plate RT2 and the second electrode CAE, thereby generating green light according to a micro cavity effect and outputting it upwards.

In the third emission region EA3 of the blue subpixel SPb, a micro cavity structure configured with the third reflective plate RT3 and the second electrode CAE which are spaced apart by a third resonant distance d3 can be implemented. Accordingly, in the third emission region EA3 of the blue subpixel SPb, white light generated from the light emitting diode OD can be reflected between the third reflective plate RT3 and the second electrode CAE, thereby generating blue light according to a micro cavity effect and outputting it upwards.

Further, a bank (or partition wall or fence) 143 positioned along a boundary (or edge) of each subpixel SP and surrounding the subpixel SP can be formed.

The bank 143 can be formed of an inorganic or organic insulating material. The bank 143 can be formed of a transparent insulating material that transmits light. For example, the bank 143 can be formed of at least one of an acrylic resin, an epoxy resin, a phenol resin, a polyamide-based resin, a polyimide-based resin, an unsaturated polyester-based resin, a polyphenylene-based resin, a polyphenylene sulfide-based resin, benzocyclobutene, and a photoresist, but not limited thereto.

The bank 143 can have an opening that exposes the main electrode AE1 of each subpixel SP, and can be formed to cover an edge of the main electrode AE1 (or the first electrode AE). By the opening of the bank 143, the emission region EA (or the light emitting diode OD) within the subpixel SP can be defined.

A trench TC can be formed in the bank 143 and at least a portion of the insulating layer(s) laminated below the bank 143. For example, the trench TC can be formed along a boundary between the subpixels SP of different colors in the column direction. Alternatively, in some cases, the trench TC can also be formed along a boundary between the subpixels SP of the same color in the row direction.

In this regard, for example, the trench TC can be formed, between the emission regions EA of adjacent subpixels SP, in the bank 143 and at least a portion of the first and second insulating layers 121 and 122 and the passivation layer 111. In this embodiment, for convenience of explanation, the case where the trench TC is formed in the bank 143, the first and second insulating layers 121 and 122, and the passivation layer 111 is taken as an example.

By forming the trench TC in this way, at least a lower portion of the light emitting layer 145 can be separated between the adjacent subpixels SP, thereby preventing (or reducing) lateral leakage current between the subpixels SP.

In this regard, the light emitting layer 145 can be, for example, an organic light emitting layer formed using an organic material. Furthermore, the light emitting layer 145 can be formed in a multi-layered structure including an emitting material layer that actually emits light.

The light emitting layer 145 can be formed in a single-stack structure or a multi-stack structure.

When the light emitting layer 145 is formed in a single-stack structure, the light emitting layer 145 can be separated by the trench TC.

When the light emitting layer 145 is formed in a multi-stack structure, a charge generation layer can be provided between adjacent stacks. In this case, for example, a lower stack and the charge generation layer located on the lower stack can be separated by the trench TC, and an upper stack can be can have a state in which at least an upper part of the upper stack is not separated over the trench TC and is connected over the trench TC.

The second electrode CAE on the light emitting layer 145 can be formed continuously between adjacent subpixels SP without being separated by the trench TC. Accordingly, the second electrode CAE can be formed substantially continuously along all subpixels SP of the display region AA.

Regarding the laminated structure of the contact region CA, referring to FIGS. 3 to 6, a micro cavity structure having a resonant distance capable of emitting the color light of each subpixel SP can be formed in the contact region CA of each subpixel SP.

For example, planarization patterns PL can be formed on the main electrodes AE1 in the contact regions (CA: CA1, CA2, and CA3) of the red, green, and blue subpixels SPr, SPg, and SPb.

The planarization pattern PL can be formed as a single-layered or multi-layered structure. The planarization pattern PL can be formed of, but not limited to, an organic insulating material.

As the planarization patterns PL are formed, the contact regions CA of the red, green, and blue subpixels SPr, SPg, and SPb can have surfaces that are substantially flat. For example, the contact regions CA of the red, green, and blue subpixels SPr, SPg, and SPb can be configured such that upper surfaces of their planarization patterns PL can be substantially flat and at the same height.

In this regard, as the first and second contact holes CH1 and CH2 are formed in the contact region CA, a surface of a layer (e.g. the third connection electrode CE3) onthe substrate 101 on which the main electrode AE1 is formed can have an uneven shape following the shapes of the first and second contact holes CH1 and CH2. When such the uneven shape exists, the main electrode AE1 can have an uneven shape and thus the micro cavity structure in the contact region CA can also have an uneven shape. This can cause light of a different color from light generated in the emission region EA to be generated in the corresponding contact region CA, resulting in a color mixing phenomenon.

However, in this embodiment, the planarization pattern PL can be formed on the main electrode AE1, so that an upper surface of the planarization pattern PL in the contact region CA can be in a substantially flat state. Accordingly, the color mixing phenomenon, which is caused by the generation of different color light in the contact region CA due to the uneven shape caused by the first and second contact holes CH1 and CH2, can be prevented or reduced.

On the planarization pattern PL, in each of the contact regions (CA: CA1, CA2, and CA3) of the red, green, and blue subpixels SPr, SPg, and SPb, a fourth reflective plate RT4, which is a reflective plate RT that implements the micro cavity structure of each contact region CA, can be formed.

Here, similar to the first to third reflective plates RT1 to RT3, the fourth reflective plate RT4 can be formed of a highly reflective metal, such as Ag, Al, Mo, Ti, or an APC (Al-Pd-Cu) alloy, but not limited thereto.

On the fourth reflective plate RT4, to implement the micro cavity structure for generating the color light of each subpixel SP in the contact region CA of each subpixel SP, different laminated structures can be formed among the subpixels SP.

In this regard, for example, in the first contact region CA1 of the red subpixel SPr, in order to set its fourth resonant distance dc1, insulating pattern(s), for example, first and second insulating patterns IL1 and IL2 can be formed on the fourth reflective plate RT4 to cover the fourth reflective plate RT4. In addition, on a laminated structure of the first and second insulating patterns IL1 and IL2, an auxiliary electrode AE2 constituting the first electrode AE of the red subpixel SPr can be formed.

Here, referring to FIG. 4, the auxiliary electrode AE2 formed in the first contact region CA1 can be formed, for example, to cover a side surface of a laminated structure, positioned below it, configured with the first and second insulating patterns IL1 and IL2, the fourth reflective plate RT4, and the planarization pattern PL. As such, the auxiliary electrode AE2 can extend along the side surface of the laminated structure below it and contact the main electrode AE1 at a boundary between the first emission region EA1 and the first contact region CA1.

Accordingly, the red subpixel SPr can be provided with the first electrode AE that is configured with the main electrode AE1 and the auxiliary electrode AE2. Furthermore, a laminated structure including the fourth reflective plate RT4 that implements the micro cavity structure of the first contact region CA1 can be formed between the main electrode AE1 and the auxiliary electrode AE2.

In the second contact region CA2 of the green subpixel SPg, in order to set its fifth resonant distance dc2, an insulating pattern, for example, a first insulating pattern IL1 can be formed on the fourth reflective plate RT4 to cover the fourth reflective plate RT4. In addition, on the first insulating pattern IL1, an auxiliary electrode AE2 constituting the first electrode AE of the green subpixel SPg can be formed.

Here, referring to FIG. 5, the auxiliary electrode AE2 formed in the second contact region CA2 can be formed, for example, to cover a side surface of a laminated structure, positioned below it, configured with the first insulating pattern IL1, the fourth reflective plate RT4, and the planarization pattern PL. As such, the auxiliary electrode AE2 can extend along the side surface of the laminated structure below it and contact the main electrode AE1 at a boundary between the second emission region EA2 and the second contact region CA2.

Accordingly, the green subpixel SPg can be provided with the first electrode AE that is configured with the main electrode AE1 and the auxiliary electrode AE2. Furthermore, a laminated structure including the fourth reflective plate RT4 that implements the micro cavity structure of the second contact region CA2 can be formed between the main electrode AE1 and the auxiliary electrode AE2.

In the third contact region CA3 of the blue subpixel SPb, in order to set its sixth resonant distance dc3, a separate insulating pattern may not be formed on the fourth reflective plate RT4. In this case, an auxiliary electrode AE2 constituting the first electrode AE of the blue subpixel SPb can be formed on the fourth reflective plate RT4.

Here, referring to FIG. 6, the auxiliary electrode AE2 formed in the third contact region CA3 can be formed, for example, to cover a side surface of a laminated structure, positioned below it, configured with the fourth reflective plate RT4 and the planarization pattern PL. As such, the auxiliary electrode AE2 can extend along the side surface of the laminated structure below it and contact the main electrode AE1 at a boundary between the third emission region EA3 and the third contact region CA3.

Accordingly, the blue subpixel SPb can be provided with the first electrode AE that is configured with the main electrode AE1 and the auxiliary electrode AE2. Furthermore, a laminated structure including the fourth reflective plate RT4 that implements the micro cavity structure of a third contact region CA3 can be formed between the main electrode AE1 and the auxiliary electrode AE2.

In the contact regions CA of the red, green, and blue subpixels SP, the bank 143 can be formed on the auxiliary electrode AE2 to cover the auxiliary electrode AE2.

As such, the bank 143 can cover the auxiliary electrode AE2 in the contact region CA of each subpixel SP, thereby preventing contact between the light emitting layer 145 and the auxiliary electrode AE2 in the contact region CA.

As such, the bank 143 can be substantially formed around the emission region EA to surround the emission region EA, so that the bank 143 can cover the non-emission region, including the contact region CA, of the subpixel SP. Accordingly, the bank 143 can cover the edge of the first electrode AE positioned along the periphery of the emission region EA. In this regard, the bank 143 can cover the edge of the main electrode AE1 and the entire auxiliary electrode AE2.

As mentioned above, the trench TC can be formed in the bank 143 and at least a portion of the insulating layer(s) laminated below the bank 143.

In this regard, for example, the trench TC can be formed, between the contact regions CA of adjacent subpixels SP, in the bank 143 and at least a portion of the first and second insulating patterns IL1 and IL2, the planarization pattern PL, the first and second insulating layers 121 and 122, and the passivation layer 111. In this embodiment, for convenience of explanation, the case in which the trench TC is formed in the bank 143, the first and second insulating patterns IL1 and IL2, the planarization pattern PL, the first and second insulating layers 121 and 122, and the passivation layer 111 is taken as an example

In the contact regions CA of the red, green, and blue subpixels SP, the light emitting layer 145 can be formed on the bank 143.

The light emitting layer 145 can be formed, for example, continuously along the emission region EA and the contact region CA of each subpixel SP. Furthermore, at least a lower portion of the light emitting layer 145 can be separated between adjacent subpixels SP by the trench TC, thereby preventing (or reducing) a lateral leakage current between the subpixels SP.

In the contact regions CA of the red, green, and blue subpixels SP, the second electrode CAE can be formed on the light emitting layer 145.

The second electrode CAE can be formed, for example, continuously along the emission region EA and the contact region CA of each subpixel SP. In addition, the second electrode CAE can be formed continuously between adjacent subpixels SP without being separated by the trench TC.

The second electrode CAE with semi-transparent characteristics, together with the fourth reflective plate RT positioned below it, can implement the micro cavity structure for the contact region CA of each subpixel SP.

For example, in the first contact region CA1 of the red subpixel SPr, the micro cavity structure configured with the fourth reflective plate RT4 and the second electrode CAE spaced apart by the fourth resonant distance dc1 can be implemented. Accordingly, in the first contact region CA1 of the red subpixel (SPr), light generated by the lateral leakage current from the first emission region EA1 can be reflected between the fourth reflective plate RT4 and the second electrode CAE, so that according to the micro cavity effect, red light of the red subpixel SPr can be generated and outputted upwards.

In the second contact region CA2 of the green subpixel SPg, the micro cavity structure configured with the fourth reflective plate RT4 and the second electrode CAE spaced apart by the fifth resonant distance dc2 can be implemented. Accordingly, in the second contact region CA2 of the green subpixel SPg, light generated by the lateral leakage current from the second emission region EA2 can be reflected between the fourth reflective plate RT4 and the second electrode CAE, so that according to the micro cavity effect, green light of the green subpixel SPg can be generated and outputted upwards.

In the third contact region CA3 of the blue subpixel SPb, the micro cavity structure configured with the fourth reflective plate RT4 and the second electrode CAE spaced apart by the sixth resonant distance dc3 can be implemented. Accordingly, in the third contact region CA3 of the blue subpixel SPb, light generated by the lateral leakage current from the third emission region EA3 can be reflected between the fourth reflective plate RT4 and the second electrode CAE, so that according to the micro cavity effect, blue light of the blue subpixel SPb can be generated and outputted upwards.

As described above, in this embodiment, regarding the contact region CA of the subpixel SP, the planarization pattern PL that flattens the uneven shape of the surface of the substrate due to the first and second contact holes CH1 and CH2 can be formed, and a laminated structure including the fourth reflective plate RT4 on the planarization pattern PL (or thickness of the laminated structure) can be differentiated according to the subpixels SP, thereby implementing the micro cavity structure having the resonant distance that emits the color light of each subpixel SP.

As such, in the contact region CA of each subpixel SP, the micro cavity structure capable of generating the color light of substantially the same wavelength as the color light of the subpixel SP can be formed on the flat surface of the planarization pattern PL.

Therefore, the color mixing, which is caused in the light output from the subpixel SP by generation of color light of the contact region CA that is different from color light of the emission region EA due to the uneven shape caused by the first and second contact holes CH1 and CH2, can be prevented or reduced, thereby improving color gamut.

Furthermore, a light output region of the subpixel SP can extend to the contact region CA, thereby enhancing an aperture ratio.

### Second Embodiment

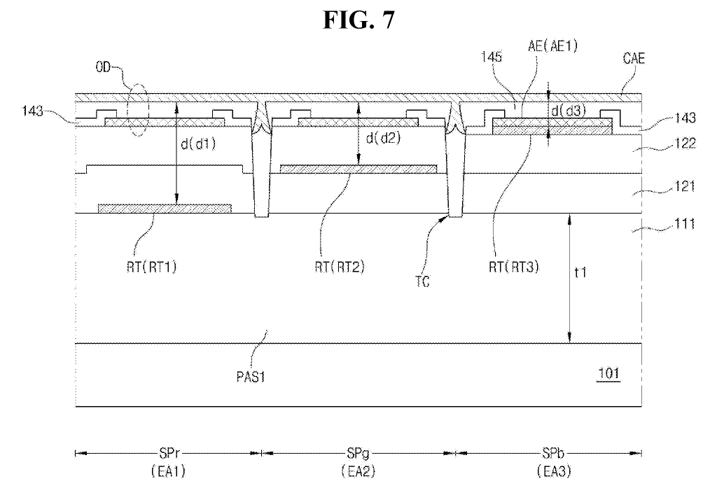

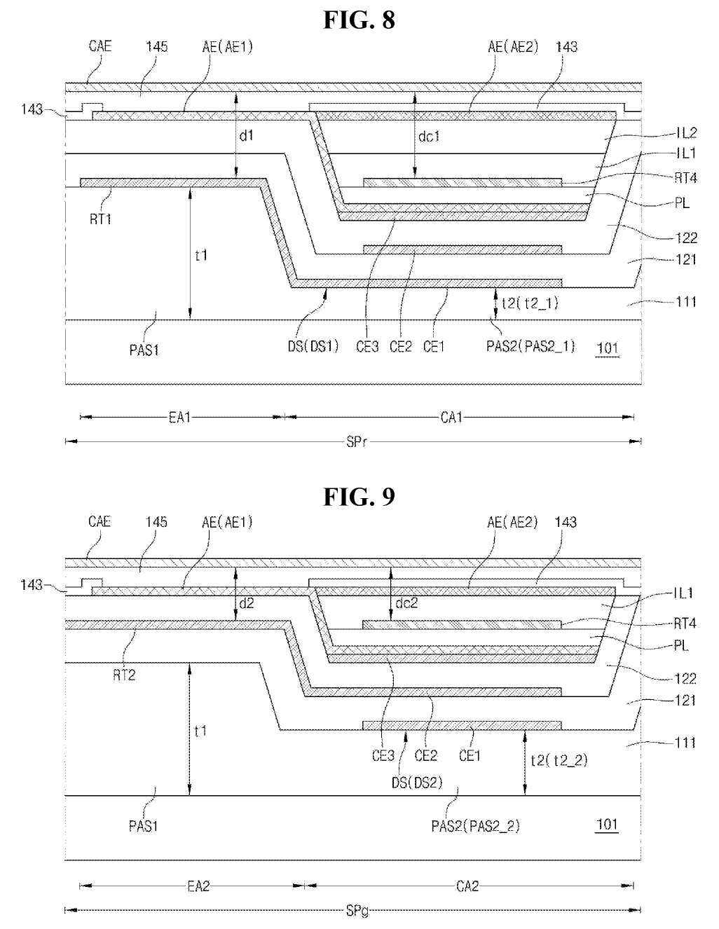

FIG. 7 is a cross-sectional view illustrating a structure of an emission region of a subpixel of a light emitting display device according to a second embodiment of the present invention, which is taken along a line similar to line II-II’ of FIG. 1. FIGS. 8, 9 and 10 are cross-sectional views illustrating structures of emission region and contact region of red, green, and blue subpixels, respectively, according to a second embodiment of the present invention, which are taken along lines similar to lines IV-IV’, V-V’, and VI-VI’ of FIG. 1, respectively.

In the following description, detailed explanations of components identical to or similar to those of the first embodiment described above can be omitted or briefly provided.

Referring to FIGS. 7 to 10, in the light emitting display device 10 of this embodiment, similar to the first embodiment, for the contact region CA of each subpixel SP, the micro cavity structure capable of generating color light having substantially the same wavelength as color light of the emission region EA of the subpixel SP can be formed.

Meanwhile, in this embodiment, when implementing the micro cavity structure in the contact region CA, a recessed space (or recessed region) DS in which the contact structure and the micro cavity structure can be accommodated (or arranged) can be formed corresponding to the contact region CA.

In this regard, in the first embodiment described above, in each subpixel SP, the contact region CA can be formed with a structure that substantially forms the micro cavity structure on the main electrode AE1 of the first electrode AE, so that the micro cavity structure of the contact region CA can be set at a higher position than the micro cavity structure of the emission region EA. Accordingly, the contact region CA can have a shape that protrudes upward compared to the emission region EA, resulting in a surface of a top layer on the substrate being uneven rather than flat.

Meanwhile, in this embodiment, the recessed space DS can be formed in the contact region CA, and the contact structure and the micro cavity structure can be arranged in the recessed space DS, so that the surfaces of the contact region CA and the emission region EA can be positioned substantially on the same plane, thereby providing an advantage that the top layer on the substrate 101 below which the light emitting diode OD is formed can have an overall flat surface.

The micro cavity structures of the emission region EA and the contact region CA of this embodiment can be described in more detail.

The passivation layer 111 can be formed on the substrate 101 on which the thin film transistor (TR in FIG. 3) is formed.

For example, the passivation layer 111 can be formed in a stepped structure with different thicknesses (or heights) between the emission region EA and the contact region EA in each subpixel SP. In this regard, in each subpixel EA, a first portion PAS1, which is a portion of the passivation layer 111 formed in the emission region EA, can have a relatively large thickness, while a second portion (or recessed portion) PAS2, which is a portion of the passivation layer 111 formed in the contact region EA, can have a relatively small thickness. Thus, the passivation layer 111 can be formed in the stepped structure in which the contact region EA is recessed within each subpixel SP.

Here, the first portion PAS1 of the passivation layer 111 can be formed, for example, with the same thickness among the red, green, and blue subpixels SPr, SPg, and SPb.

The second portion PAS2 of the passivation layer 111 can have, for example, different thicknesses among the red, green, and blue subpixels SPr, SPg, and SPb.

In this regard, for example, for the red subpixel SPr, the first portion PAS1 of the passivation layer 111 formed in the first emission region EA1 can have a first thickness t1, and the second portion PAS2 of the passivation layer 111 formed in the first contact region CA1 i.e., a second, first portion PAS2_1 can have a second thickness t2 smaller than the first thickness t1 i.e., a second, first thickness t2_1. In other words, an upper surface of the second, first portion PAS2_1 of the passivation layer 111 can be positioned at a lower height than an upper surface of the first portion PAS1. In this case, an inclined surface can be formed at a boundary between the first portion PAS1 and the second, first portion PAS2_1.

As such, in the red subpixel SPr, the first contact region CA1 can be recessed to a thickness smaller than the first emission region EA1, so that a stepped structure can be formed between the first emission region EA1 and the first contact region CA1. Furthermore, in the first contact region CA1, due to its recessed shape, a first recessed space DS1 as the recessed space DS can be defined. A depth of the first recessed space DS1 can be set so as to implement the fourth resonant distance dc1 of the micro cavity structure formed in the first contact region CA1.

For the green subpixel SPg, the first portion PAS1 of the passivation layer 111 formed in the second emission region EA2 can have the first thickness t1. In addition, the second portion PAS2 of the passivation layer 111 formed in the second contact region CA2 i.e., a second, second portion PAS2_2 can have a second thickness t2 smaller than the first thickness t1 i.e., a second, second thickness t2_2. In other words, an upper surface of the second, second portion PAS2_2 of the passivation layer 111 can be positioned at a lower height than an upper surface of the first portion PAS1. In this case, an inclined surface can be formed at a boundary between the first portion PAS1 and the second, second portion PAS2_2.

As such, the first portion PAS1 of the green subpixel SPg can be formed with substantially the same thickness as the first portion PAS1 of the red subpixel SPr, so that the emission regions EA of the green and red subpixels SPg and SPr can be formed with the same thickness of the passivation layer 111.

In addition, the second, second portion PAS2_2 of the green subpixel SPg can be formed with a greater thickness than the second, first portion PAS2_1 of the red subpixel SPr (i.e., t2_2 > t2_1), so that the contact regions CA of the green and red subpixels SPg and SPr can be formed with the passivation layer 111 having different thicknesses.

As such, in the green subpixel SPg, the second contact region CA2 can be recessed to a thickness smaller than the second emission region EA2, so that a stepped structure can be formed between the second emission region EA2 and the second contact region CA2. Furthermore, in the second contact region CA2, due to its recessed shape, a second recessed space DS2 as the recessed space DS can be defined. A depth of the second recessed space DS2 can be set so as to implement the fifth resonant distance dc2 of the micro cavity structure formed in the second contact region CA2. In this regard, the depth of the second recessed space DS2 of the green subpixel SPg can be formed to be smaller than that of the first recessed space DS1 of the red subpixel SPr.

For the blue subpixel SPb, the first portion PAS1 of the passivation layer 111 formed in the third emission region EA3 can have the first thickness t1. In addition, the second portion PAS2 of the passivation layer 111 formed in the third contact region CA3 i.e., a second, third portion PAS2_3 can have a second thickness t2 smaller than the first thickness t1 i.e., a second, third thickness t2_3. In other words, an upper surface of the second, third portion PAS2_3 of the passivation layer 111 can be positioned at a lower height than an upper surface of the first portion PAS1. In this case, an inclined surface can be formed at a boundary between the first portion PAS1 and the second, third portion PAS2_3.

As such, the first portion PAS1 of the blue subpixel SPb can be formed with substantially the same thickness as the first portions PAS1 of the red and green subpixels SPr and SPg, so that the emission regions EA of the blue, green, and red subpixels SPb, SPg, and SPr can be formed with the same thickness of the passivation layer 111.

In addition, the second, third portion PAS2_3 of the blue subpixel SPb can be formed with a greater thickness than the second, second portion PAS2_2 of the green subpixel SPg (i.e., t2_3 > t2_2), so that the contact regions CA of the blue, green, and red subpixels SPb, SPg, and SPr can be formed with the passivation layer 111 having different thicknesses.

As such, in the blue subpixel SPb, the third contact region CA3 can be recessed to a thickness smaller than the third emission region EA3, so that a stepped structure can be formed between the third emission region EA3 and the third contact region CA3. Furthermore, in the third contact region CA3, due to its recessed shape, a third recessed space DS3 as the recessed space DS can be defined. A depth of the third recessed space DS3 can be set so as to implement the sixth resonant distance dc3 of the micro cavity structure formed in the third contact region CA3. In this regard, the depth of the third recessed space DS3 of the blue subpixel SPb can be formed smaller than that of the second recessed space DS2 of the green subpixel SPg.

As described above, the passivation layer 111 can be formed in the stepped structure with the contact region CA recessed in each subpixel SP.

On the substrate 101 on which the passivation layer 111 is formed, the first reflective plate RT1 implementing the micro cavity structure corresponding to the red subpixel SPr, more specifically, the first emission region EA1 can be formed.

In addition, on the passivation layer 111, the first connection electrode CE1 can be formed in the contact region CA of each subpixel SP. In this regard, the first connection electrode CE1 can be formed on the recessed second portion PAS2 of the passivation layer 111.

For example, with further reference to FIG. 3, the first connection electrode CE1 formed in the contact region CA can be connected to the thin film transistor TR by making contact with the conductive pattern 115 filling the drain contact hole CHd.

In the red subpixel SPr, the first reflective plate RT1 and the first connection electrode CE1 can be formed integrally.

The first insulating layer 121 can be formed on the substrate 101 on which the first reflective plate RT1 and the first connection electrode CE1 are formed. The first insulating layer 121 can be formed in a stepped structure that follows and is substantially identical to the stepped structure of the passivation layer 111 therebelow.

Accordingly, substantially similar to the passivation layer 111, a height of an upper surface of the first insulating layer 121 can also be differentiated among the contact regions CA of the red, green, and blue subpixels SPr, SPg, and SPb.

With further reference to FIG. 3, in the first insulating layer 121, the first contact hole CH1 exposing the first connection electrode CE1 in the contact region CA of each subpixel SP can be formed.

On the substrate 101 on which the first insulating layer 121 is formed, the second reflective plate RT2 implementing the micro cavity structure corresponding to the green subpixel SPg, and more specifically, the second emission region EA2 can be formed.

On the first insulating layer 121, the second connection electrode CE2 can be formed in the contact region CA of each subpixel SP. In this regard, the second connection electrode CE2 can be formed on a portion of the first insulating layer 121 located in the recessed space DS.

In the green subpixel SPg, the second reflective plate RT2 and the second connection electrode CE2 can be formed integrally.

The second insulating layer 122 can be formed on the substrate 101 on which the second reflective plate RT2 and the second connection electrode CE2 are formed. The second insulating layer 122 can be formed in a stepped structure that follows and is substantially identical to the stepped structure of the passivation layer 111 and the first insulating layer 121 therebelow.

Accordingly, substantially similar to the passivation layer 111 and the first insulating layer 121, a height of an upper surface of the second insulating layer 122 can also be differentiated among the contact regions CA of the red, green, and blue subpixels SPr, SPg, and SPb.

With further reference to FIG. 3, in the second insulating layer 122, the second contact hole CH2 exposing the second connection electrode CE2 in the contact region CA of each subpixel SP can be formed.

On the substrate 101 where the second insulating layer 122 is formed, the third reflective plate RT3 implementing the micro cavity structure corresponding to the blue subpixel SPb, more specifically, the third emission region EA3 can be formed.

On the second insulating layer 122, the third connection electrode CE3 can be formed in the contact region CA of each subpixel SP. In this regard, the third connection electrode CE3 can be formed on a portion of the second insulating layer 122 located in the recessed space DS.

In the blue subpixel SPb, the third reflective plate RT3 and the third connection electrode CE3 can be formed integrally.

On the substrate 101 having the third reflective plate RT3 and the third connection electrode CE3, the main electrode AE1 of the first electrode AE constituting the light emitting diode OD of each subpixel SP can be formed.

The main electrode AE1 can be formed in a continuous form along the emission region EA and the contact region CA of each subpixel SP. The main electrode AE1 can be formed in a stepped structure that follows and is substantially identical to the step structure of the passivation layer 111 and the first and second insulating layers 121 and 122 therebelow.

On the substrate 101 having the main electrode AE1, in the recessed space DS of the contact region CA of each subpixel SP, the micro cavity structure having the resonant distance capable of emitting color light of the subpixel SP can be formed.

For example, in the contact regions (CA: CA1, CA2, and CA3) of the red, green, and blue subpixels SPr, SPg, and SPb, the planarization pattern PL can be formed on the main electrode AE1.

On the planarization pattern PL, in each of the contact regions (CA: CA1, CA2, and CA3) of the red, green, and blue subpixels SPr, SPg, and SPb, the fourth reflective plate RT4, which is the reflective plate RT that implements the micro cavity structure in each contact region CA, can be formed.

On the fourth reflective plate RT4, to implement the micro cavity structure for emitting the color light of each subpixel SP, different laminated structures among the subpixels SP can be formed.

In this regard, referring to FIG. 8, in the first recessed space DS1 of the first contact region CA1 of the red subpixel SPr, in order to set its fourth resonant distance dc1, insulating pattern(s), for example, first and second insulating patterns IL1 and IL2 can be formed on the fourth reflective plate RT4 to cover the fourth reflective plate RT4. In addition, on a laminated structure of the first and second insulating patterns IL1 and IL2, the auxiliary electrode AE2 constituting the first electrode AE of the red subpixel SPr can be formed.

Here, a laminated structure of the planarization pattern PL, the fourth reflective plate RT4, the first and second insulating patterns IL1 and IL2, and the auxiliary electrode AE2 formed in the first contact region CA1 can be formed to substantially fill a recessed space defined by a portion of the main electrode AE1 in the first contact region CA1.

The auxiliary electrode AE2 can be formed to contact the main electrode AE1 at a boundary between the first emission region EA1 and the first contact region CA1.

Accordingly, the red subpixel SPr can be provided with the first electrode AE configured with the main electrode AE1 and the auxiliary electrode AE2. Furthermore, a laminated structure including the fourth reflective plate RT4 that implements the micro cavity structure of the first contact region CA1 can be formed between the main electrode AE1 and the auxiliary electrode AE2.

As such, in this embodiment, a laminated structure implementing the micro cavity structure can be accommodated in the first recessed space DS1 of the first contact region CA1. Thus, in the red subpixel SPr, the first emission region EA1 and the first contact region CA1 can be formed with a substantially flat surface.

Referring to FIG. 9, in the second recessed space DS2 of the second contact region CA2 of the green subpixel SPg, in order to set its fifth resonant distance dc2, an insulating pattern, for example, a first insulating pattern IL1 can be formed on the fourth reflective plate RT4. In addition, the auxiliary electrode AE2 constituting the first electrode AE of the green subpixel SPg can be formed on the first insulating pattern IL1.

Here, a laminated structure of the planarization pattern PL, the fourth reflective plate RT4, the first insulating pattern IL1, and the auxiliary electrode AE2 formed in the second contact region CA2 can be formed to substantially fill a recessed space defined by a portion of the main electrode AE1 in the second contact region CA2.

The auxiliary electrode AE2 can be formed to contact the main electrode AE1 at a boundary between the second emission region EA2 and the second contact region CA2.

Accordingly, the green subpixel SPg can be provided with the first electrode AE configured with the main electrode AE1 and the auxiliary electrode AE2. Furthermore, a laminated structure including the fourth reflective plate RT4 that implements the micro cavity structure of the second contact region CA2 can be formed between the main electrode AE1 and the auxiliary electrode AE2.

In this embodiment, a laminated structure implementing the micro cavity structure can be accommodated in the second recessed space DS2 of the second contact region CA2. Thus, in the green subpixel SPg, the second emission region EA2 and the second contact region CA2 can be formed with a substantially flat surface.

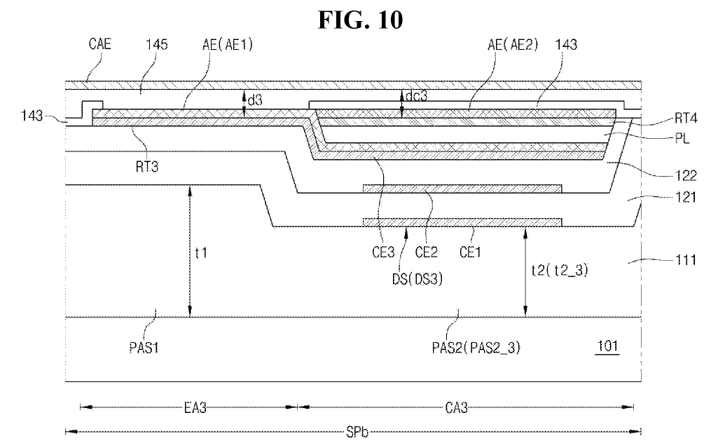

Referring to FIG. 10, in the third recessed space DS3 of the third contact region CA3 of the blue subpixel SPb, in order to set its sixth resonant distance dc3, a separate insulating pattern may not be formed on the fourth reflective plate RT4. In this case, the auxiliary electrode AE2 constituting the first electrode AE of the blue subpixel SPb can be formed on the fourth reflective plate RT4.

Here, a laminated structure of the planarization pattern PL, the fourth reflective plate RT4, and the auxiliary electrode AE2 formed in the third contact region CA3 can be formed to substantially fill a recessed space defined by a portion of the main electrode AE1 in the third contact region CA3.

The auxiliary electrode AE2 can be formed to contact the main electrode AE1 at a boundary between the third emission region EA3 and the third contact region CA3.

Accordingly, the blue subpixel SPb can be provided with the first electrode AE configured with the main electrode AE1 and the auxiliary electrode AE2. Furthermore, a laminated structure including the fourth reflective plate RT4 that implements the micro cavity structure of the third contact region CA3 can be formed between the main electrode AE1 and the auxiliary electrode AE2.

As such, in this embodiment, a laminated structure implementing the micro cavity structure can be accommodated in the third recessed space DS3 of the third contact region CA3. Thus, in the blue subpixel SPb, the third emission region EA3 and the third contact region CA3 can be formed with a substantially flat surface.

In the contact regions CA of the red, green, and blue subpixels SP, the bank 143 can be formed on the auxiliary electrode AE2 to cover the auxiliary electrode AE2.

As such, the bank 143 can be substantially formed around the emission region EA to surround the emission region EA, thereby covering the non-emission region, including the contact region CA, of the subpixel SP. Accordingly, the bank 143 can cover the edge of the first electrode AE positioned along the periphery of the emission region EA.

The trench TC can be formed in the bank 143 and at least a portion of the insulating layer(s) laminated below the bank 143, similar to the first embodiment.

The light emitting layer 145 and the second electrode CAE can be formed on the substrate 101 on which the first electrode AE and the bank 143 are formed.

The light emitting layer 145 and the second electrode CAE can be formed in a substantially flat state in each subpixel SP. Accordingly, the light emitting layer 145 and the second electrode CAE can be formed in a substantially flat state in the display region AA.

By forming the second electrode CAE with semi-transparent characteristics, in the emission region EA and the contact region CA of each subpixel SP, the micro cavity structure that implements the color of the subpixel SP can be formed.

### Third Embodiment

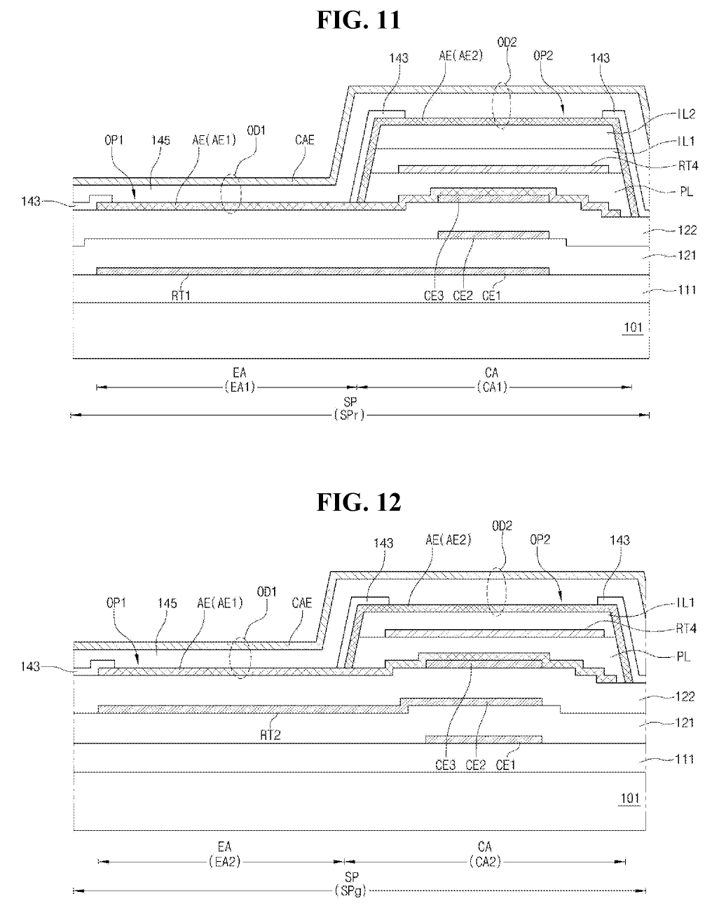

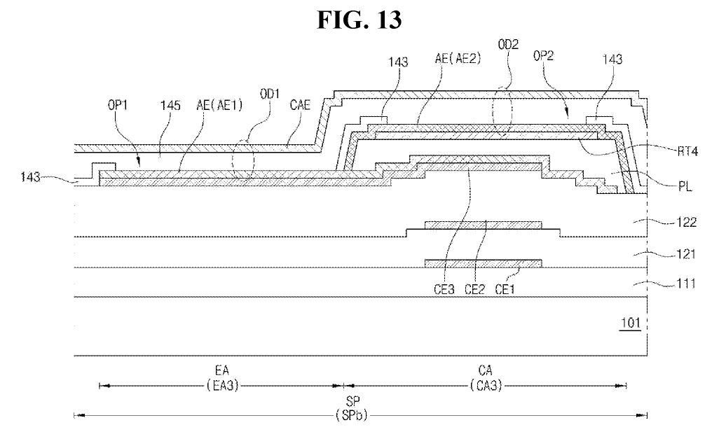

FIGS. 11, 12 and 13 are cross-sectional views illustrating structures of emission region and contact region of red, green, and blue subpixels, respectively, according to a third embodiment of the present invention, which are taken along lines similar to lines IV-IV’, V-V’, and VI-VI’ of FIG. 1, respectively.

In the following description, detailed explanations of components identical or similar to those of the first embodiment described above can be omitted or briefly provided.

Referring to FIGS. 11 to 13, in the light emitting display device of this embodiment, similar to the first embodiment, for the contact region CA of each subpixel SP, the micro cavity structure capable of generating color light having substantially the same wavelength as color light of the emission region EA of the subpixel SP can be formed.

In this embodiment, a light emitting diode can be additionally configured in the contact region CA of each subpixel SP. Accordingly, the contact region CA can also function as an effective emission region, resulting in an increase in an emission area of the subpixel SP.

In this regard, for example, for each of the red, green, and blue subpixels SPr, SPg, and SPb, the bank 143 can have a first opening OP1 which is an opening exposing the main electrode AE1 of the first electrode AE in the emission region EA, similar to the first embodiment.

Thus, a first light emitting diode OD1, which is a light emitting diode configured with the main electrode AE1, the light emitting layer 145, and the second electrode CAE laminated in the first opening OP1, can be formed in the emission region EA. The first light emitting diode OD1 can substantially serve as a primary (or main) light emitting diode of the subpixel SP, and the emission region EA where the first light emitting diode OD1 is formed can function as a primary (or main) emission region.

Furthermore, for each of the red, green, and blue subpixels SPr, SPg, and SPb, the bank 143 can have a second opening OP2 which is an opening exposing the auxiliary electrode AE2 of the first electrode AE in the contact region CA.

Accordingly, a second light emitting diode OD2, which is a light emitting diode configured with the auxiliary electrode AE2, the light emitting layer 145, and the second electrode CAE laminated in the second opening OP2, can be formed in the contact region CA. The second light emitting diode OD2 can substantially serve as an auxiliary light emitting diode of the subpixel SP, and the contact region CA where the second light emitting diode OD2 is formed can function as an auxiliary emission region.

As described above, in this embodiment, the light emitting diode OD2 can be additionally formed in the contact region CA, thereby increasing the emission area of the subpixel SP. Accordingly, the emission efficiency of the light emitting display device can be improved.

### Fourth Embodiment

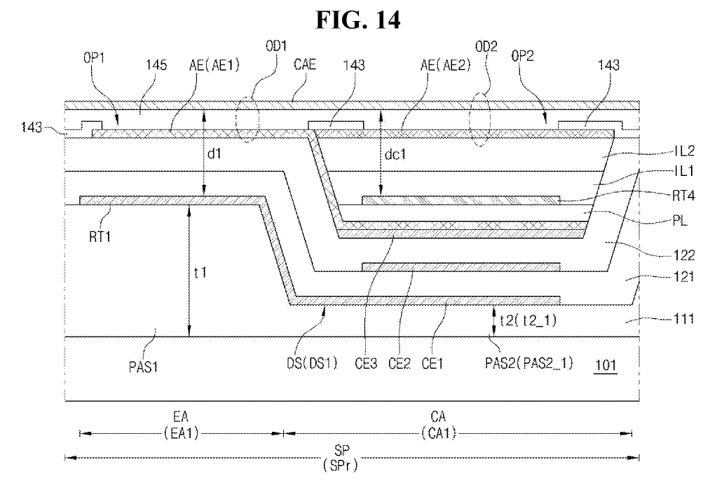

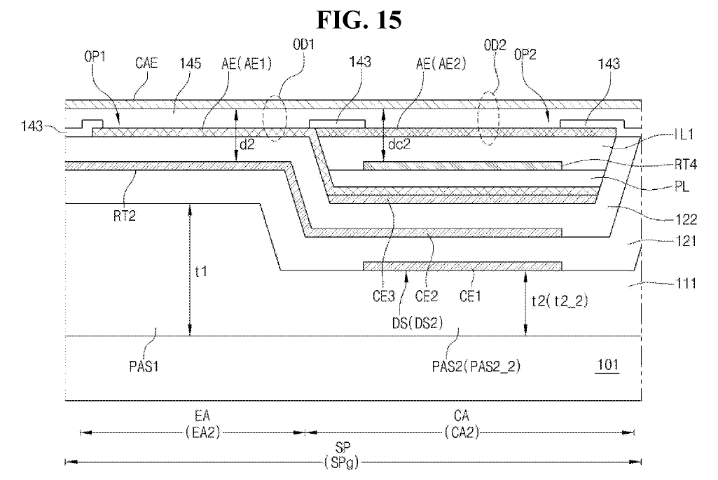

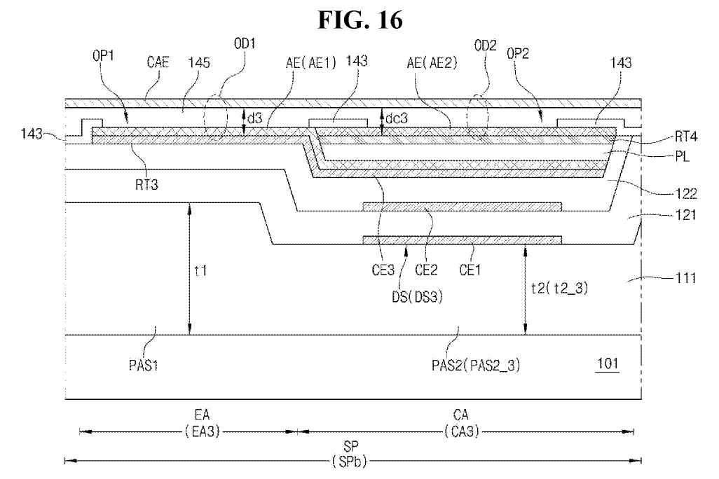

FIGS. 14, 15 and 16 are cross-sectional views illustrating structures of emission region and contact region of red, green, and blue subpixels, respectively, according to a fourth embodiment of the present invention.

In the following description, detailed explanations of components identical or similar to those of the second embodiment can be omitted or briefly provided.

Referring to FIGS. 14 to 16, in the light emitting display device of this embodiment, similarly to the second embodiment, for the contact region CA of each subpixel SP, the micro cavity structure capable of generating color light having substantially the same wavelength as color light of the emission region EA of the subpixel SP can be formed.

In this embodiment, a light emitting diode can be additionally configured in the contact region CA of each subpixel SP. Accordingly, the contact region CA can also function as an effective emission region, resulting in an increase in an emission area of the subpixel SP.

In this regard, for example, for each of the red, green, and blue subpixels SPr, SPg, and SPb, the bank 143 can have a first opening OP1 which is an opening exposing the main electrode AE1 of the first electrode AE in the emission region EA, similar to the second embodiment.

Accordingly, a first light emitting diode OD1, which is a light emitting diode configured with the main electrode AE1, the light emitting layer 145, and the second electrode CAE laminated in the first opening OP1, can be formed in the emission region EA. The first light emitting diode OD1 can substantially serves as a primary (or main) light emitting diode of the subpixel SP, and the emission region EA where the first light emitting diode OD1 is formed can function as a primary (or main) emission region.

Furthermore, for each of the red, green, and blue subpixels SPr, SPg, and SPb, the bank 143 can have a second opening OP2 which is an opening exposing the auxiliary electrode AE2 of the first electrode AE in the contact region CA.

Accordingly, a second light emitting diode OD2, which is a light emitting diode configured with the auxiliary electrode AE2, the light emitting layer 145, and the second electrode CAE laminated in the second opening OP2, can be formed in the contact region CA. The second light emitting diode OD2 can substantially serve as an auxiliary light emitting diode of the subpixel SP, and the contact region CA where the second light emitting diode OD2 is formed can function as an auxiliary emission region.

As described above, in this embodiment, the second light emitting diode OD2 can be additionally formed in the contact region CA, thereby increasing the emission area of the subpixel SP. Accordingly, the emission efficiency of the light emitting display device can be improved.

In the above-described embodiments, for convenience of explanation, the reflective plates arranged in the emission regions of the red, green, and blue subpixels are referred to as the first to third reflective plates, and the reflective plate arranged in the contact region of each subpixel is referred to as the fourth reflective plate. Meanwhile, in some cases, the reflective plate arranged in the emission region of each subpixel can be referred to as a first reflective plate, and the reflective plate arranged in the contact region of each subpixel can be referred to as a second reflective plate.

As described above, according to the embodiments of the present invention, in the contact region of the subpixel, the planarization pattern can be formed to flatten the uneven surface of the layer below it and on the substrate (e.g. the main electrode AE1)due to the contact hole, and a laminated structure including the reflective plate on the planarization pattern can be differentiated according to the subpixels, thereby implementing the micro cavity structure having the resonant distance that emits the color light of the subpixel.

As such, in the contact region of each subpixel, the micro cavity structure capable of emitting the color light of substantially the same wavelength as the color light of the subpixel can be formed in a substantially flat shape without unevenness.

Therefore, the color mixing, which is caused in the light output from the subpixel by generation of the color light of the contact region that is different from the color light of the emission region due to the uneven shape caused by the contact holes, can be prevented or reduced, thereby improving color gamut.

The light output region of the subpixel can extend to the contact region, thereby enhancing an aperture ratio.

Further, the recessed space can be formed in the contact region, and the micro cavity structure can be positioned in the recessed space. In this case, the surfaces of the contact region and the emission region can be positioned substantially on the same plane, so that the rop layer on the substrate with the light emitting diode formed below it can have an overall flat surface.

Furthermore, a light emitting diode can be additionally configured in the contact region, thereby increasing the emission area of the subpixel. Consequently, the emission efficiency of the light emitting display device can be improved.

It will be apparent to those skilled in the art that various modifications and variation can be made in the present invention without departing from the spirit or scope of the invention Thus, it is intended that the present invention cover the modifications and variations of this invention provided they come within the scope of the appended claims and their equivalents.

What is claimed is:

1. A light emitting display device, comprising:
a substrate including a plurality of subpixels each including an emission region and a contact region;
a first reflective plate disposed in the emission region on the substrate;
a first electrode including a main electrode and laminated on the first reflective plate;
a light emitting layer laminated on the main electrode;
a second electrode laminated on the light emitting layer and being semi-transparent, wherein the main electrode, the light emitting layer and the second electrode are disposed in the emission region and the contact region, and
a laminated structure in the contact region and interposed between the main electrode and the light emitting layer, the laminated structure including a planarization pattern on the main electrode and a second reflective plate on the planarization pattern,
wherein a micro cavity structure configured with the first reflective plate and the second electrode in the emission region generates light of a same color as a micro cavity structure configured with the second reflective plate and the second electrode in the contact region.

2. The light emitting display device of claim 1, wherein the plurality of subpixels include a red subpixel, a green subpixel, and a blue subpixel, and
wherein the laminated structure in the contact region of the red subpixel further includes a first insulating pattern and a second insulating pattern laminated on the second reflective plate.

3. The light emitting display device of claim 2, wherein the laminated structure in the contact region of the green subpixel further includes the first insulating pattern laminated on the second reflective plate.

4. The light emitting display device of claim 3, wherein the laminated structure of the contact region of the red subpixel includes an auxiliary electrode of the first electrode disposed on the second insulating pattern,
wherein the laminated structure of the contact region of the green subpixel includes the auxiliary electrode of the first electrode disposed on the first insulating pattern, and
wherein the laminated structure of the contact region of the blue subpixel includes the auxiliary electrode of the first electrode disposed on the second reflective plate.

5. The light emitting display device of claim 4, wherein the auxiliary electrode is in contact with the main electrode at a boundary between the emission region and the contact region of the subpixel.

6. The light emitting display device of claim 4, further comprising a bank in the contact region,
wherein the bank is disposed between the auxiliary electrode and the light emitting layer, and covers the auxiliary electrode.

7. The light emitting display device of claim 6, wherein the bank covers an edge of the main electrode.

8. The light emitting display device of claim 1, wherein a contact hole is disposed in the contact region to electrically connect a thin film transistor of the subpixel and the main electrode, and
wherein the planarization pattern flattens an uneven shape of the main electrode caused by the contact hole.

9. The light emitting display device of claim 1, wherein the micro cavity structure in the contact region is disposed at a higher position than the micro cavity structure in the emission region.

10. The light emitting display device of claim 1, further comprising a passivation layer disposed below the first reflective plate, and recessed in the contact region to define a recessed space,
wherein the laminated structure in the contact region is accommodated in the recessed space.

11. The light emitting display device of claim 10, wherein the plurality of subpixels include a red subpixel, a green subpixel, and a blue subpixel,
wherein a portion of the passivation layer in the contact region of the red subpixel has a thickness smaller than a portion of the passivation layer in the contact region of the green subpixel, and
wherein the portion of the passivation layer in the contact region of the green subpixel has a thickness smaller than a portion of the passivation layer in the contact region of the blue subpixel.

12. The light emitting display device of claim 10, wherein the plurality of subpixels include a red subpixel, a green subpixel, and a blue subpixel,
wherein the recessed space of the red subpixel is deeper than the recessed space of the green subpixel, and
wherein the recessed space of the green subpixel is deeper than the recessed space of the blue subpixel.

13. The light emitting display device of claim 11, wherein portions of the passivation layer in the emission regions of the red, green, and blue subpixels have a same thickness.

14. The light emitting display device of claim 4, further comprising a bank including a first opening exposing the main electrode in the emission region and a second opening exposing the auxiliary electrode in the contact region.

15. The light emitting display device of claim 14, wherein the main electrode, the light emitting layer, and the second electrode laminated in the first opening form a first light emitting diode, and
wherein the auxiliary electrode, the light emitting layer, and the second electrode laminated in the second opening form a second light emitting diode.

16. A light emitting display device, comprising:
a substrate including at least one subpixel having an emission region and a contact region;
a first reflective plate disposed in the emission region;
a main electrode of a first electrode, a light emitting layer, and a second electrode, which are laminated on the first reflective plate, and are disposed in the emission region and the contact region;
a laminated structure in the contact region, and including a planarization pattern and a second reflective plate on the planarization pattern; and
a passivation layer disposed below the first reflective plate and recessed in the contact region to form a recessed space,
wherein the laminated structure of the contact region is disposed in the recessed space.

17. The light emitting display device of claim 16, wherein the at least one subpixel includes a red subpixel, a green subpixel, and a blue subpixel, and
wherein the laminated structure of the contact region of the red subpixel includes a first insulating pattern and a second insulating pattern laminated on the second reflective plate.

18. The light emitting display device of claim 16, wherein a contact hole is disposed in the contact region to electrically connect a thin film transistor of the at least one subpixel and the main electrode.

19. The light emitting display device of claim 16, wherein a micro cavity structure composed of the first reflective plate and the second electrode in the emission region is configured to generate light of a same color as a micro cavity structure composed of the second reflective plate and the second electrode in the contact region.

20. The light emitting display device of claim 19, wherein the micro cavity structure of the contact region is disposed at a higher position than the micro cavity structure of the emission region.
